(19) United States
(12) Patent Application Publication
(10) Pub. No.: US 2008/0180898 A1
(43) Pub. Date: Jul. 31, 2008

(54) SPORTS BALL COMPUTER WITH CONCEALED MOTORIZED SCREEN IN BASE

(76) Inventor: Cecil Terrell Henderson, Glen Cove, NY (US)

Correspondence Address: CARTER, DELUCA, FARRELL & SCHMIDT, LLP, 445 BROAD HOLLOW ROAD, SUITE 225, MELVILLE, NY, 11747, US

(21) Appl. No.: 11/936,378

(22) Filed: Nov. 7, 2007

Related U.S. Application Data
(60) Provisional application No. 60/887,427, filed on Jan. 31, 2007.

(51) Int. Cl. H05K 5/02

(52) U.S. Cl. 361/683

(57) ABSTRACT

A sports-inspired computer is presented which has a neat, uncluttered appearance when deactivated. In an embodiment, the computer resembles an authentic sports ball memorabilia display when deactivated. The computer includes a motorized flat panel display screen that is hidden from view when the computer is not in use. The screen incorporates a camera for capturing still and moving images, and for videoconferencing. When the computer is powered on, the screen automatically extends from the computer enclosure and assumes an upright posture for viewing. After use, the screen automatically folds back into the enclosure. The present disclosure also provides for voice activation of the computer, whereby spoken commands can cause the computer to power up and shut down. The computer also features a wireless keyboard with an integrated pointing device, which is stored in a storage compartment provided within the computer enclosure.

### CROSS REFERENCE TO RELATED APPLICATION

The present application claims the benefit of priority to U.S. Provisional Patent Application Ser. No. 60/887,427 filed on Jan. 31, 2007, the entire content of which is incorporated by reference herein.

### BACKGROUND

1. Technical Field

The present disclosure relates to devices having a video display, such as a personal computer or a television. In particular, the present disclosure is directed to a computer having an enclosure which resembles a sports ball mounted upon a display stand of the type commonly used to display sports memorabilia, such as basketballs, footballs, soccer balls, helmets and the like.

2. Background of Related Art

Desktop computer systems typically include a keyboard and a mouse, a display unit such as an LCD or CRT monitor, and a system enclosure that houses a motherboard, at least one processor, memory, hard disk storage, an optical disc reader or writer such as a CD-ROM or DVD R+W drive, I/O interfaces such as PS/2 keyboard and mouse interfaces, at least one display interface such as a SVGA, DVI or HDMI interface, analog and/or SP/DIF audio ports, and data interfaces such as USB or IEEE 1394. The system enclosure is usually mounted on the floor beneath the desktop, or on the desktop itself. Some computers, for example, the Apple iMac™ or Gateway One™, house within the display unit the motherboard and other components that would normally be housed within the system enclosure.

Another aspect of prior computer designs is that, when the computer is not in use, i.e. powered off or in standby and/or sleep mode, many people consider the darkened computer screen and the associated keyboard, mouse, cables, wires and the like, to be an unattractive eyesore. Prior computers also consume a considerable amount of desk space which is unavailable for other purposes when the computer is not in use. Attempts to conceal an inactive computer with, for example, dust covers, have met with little success because such covers are themselves often unsightly, and must be stored while the computer is in use lest the dust cover become yet another eyesore.

A continuing need exists for a computer system which better utilizes space, may reflect the style, taste and interests of the consumer, and which presents an attractive appearance when not in use.

### SUMMARY

It is an aspect of the present disclosure to provide a personal computer which, when not in use, has the appearance of an authentic sports memorabilia display. In an embodiment, the disclosed computer includes a storage drive enclosure having the appearance of a sports ball such as, for example, a basketball, volleyball, football, soccer ball, and the like, mounted atop a base. The ball can be sized in accordance with league regulations, i.e. “official” size, or the ball can be smaller or larger than official size. The ball can be constructed of the same materials from which an official ball is made, such as leather, pigskin, and the like, and/or can be constructed of materials such as polymers, fiberglass, fiber reinforced plastic (FRP), carbon fiber (CF), or other suitable materials. The ball can include predetermined indicia thereon, for example, at least one authentic or reproduction autograph of, for example, a celebrity athlete.

Included within the ball is at least one storage drive, such as a CD or DVD drive as is well-known in the art. In one embodiment, the at least one storage drive has a media tray which extends from the exterior surface of the ball for loading and unloading media, and retracts into the ball for use. The media tray has a face plate which is textured to resemble the overall texture of the ball such that, when retracted, the face plate of the media tray is flush with, and visually blends with, the outer surface of the ball.

In another aspect of the present disclosure, the base includes a motorized display assembly which has a deactivated position for storage and an activated position for viewing. The display assembly includes a screen that is pivotally mounted between at least one extending member. In the deactivated position, the at least one extending member is retracted whereby the screen is stored within the base in a substantially horizontal orientation. Upon activation of the computer, a motorized drive causes the screen to automatically move outward from its stored position within a storage compartment in a drawer-like fashion. After the screen has completely cleared the base, it automatically pivots into an activated position having a raised posture suitable for viewing by the user. In an embodiment, the activated position is user-adjustable. Upon deactivation of the computer, the motorized drive automatically pivots the screen into alignment with the storage compartment, and automatically retracts the screen into the storage compartment. Other embodiments are envisioned wherein the screen edge has a surface which is textured to resemble the overall texture of the base such that, when retracted, the edge of the screen is flush with, and visually blends with, the outer surface of the base; and/or wherein the screen is concealed behind a door when in the deactivated position. The screen can additionally include a camera for capturing still images and/or video.

The base is a system enclosure that includes a motherboard having at least one processor, a power supply unit; at least one storage device such as a hard drive; a wireless interface for communicating with a wireless keyboard assembly having an integrated pointing device as will be further described hereinbelow; a display interface; and a voice activation module for receiving spoken commands for activating the computer. The base can additionally include other interfaces and/or subassemblies well-known to the skilled artisan, such as, for example, analog and/or S/PDIF audio ports; data interfaces such as USB or IEEE 1394; and/or at least one memory card interface configured to read and write CompactFlash (CF), Secure Digital (SD) and/or MultiMediaCard (MMC) devices, for example. The base further includes an elongate cavity that forms a recess for storing the wireless keyboard assembly when not in use.

### BRIEF DESCRIPTION OF THE DRAWINGS

Various embodiments of the present disclosure will be described herein below with reference to the figures wherein:

FIG. 1 is a perspective view of an embodiment of a computer in the powered-off state in accordance with the present disclosure;

FIG. 2 is a perspective view of an embodiment of a computer having a keyboard which has been moved from a stored position to an active position in accordance with the present disclosure;

FIG. 3 is a perspective view of an embodiment of a computer in a powering-up state wherein the screen moving from the stored position to the viewing position in accordance with the present disclosure;

FIG. 4 is a perspective view of an embodiment of a computer in the powered-on state wherein the screen is in the viewing position in accordance with the present disclosure;

FIG. 5 is a perspective view of an embodiment of a computer in the powered-on state showing the storage drive tray in an open state; and

FIG. 6 is a schematic diagram of a sports ball computer in accordance with the present disclosure.

### DETAILED DESCRIPTION

Embodiments of the present disclosure will be described hereinbelow with reference to the accompanying drawings. In the following description, well-known functions or constructions are not described in detail to avoid obscuring the present disclosure with unnecessary detail.

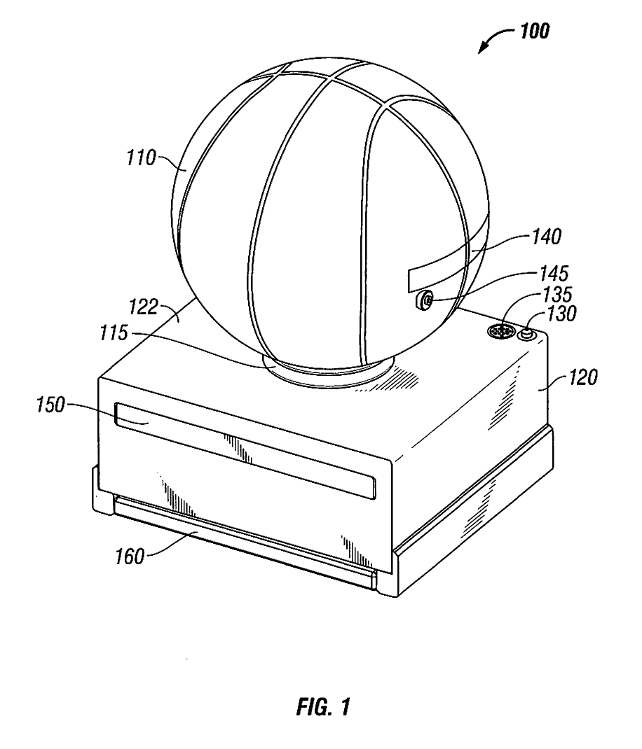

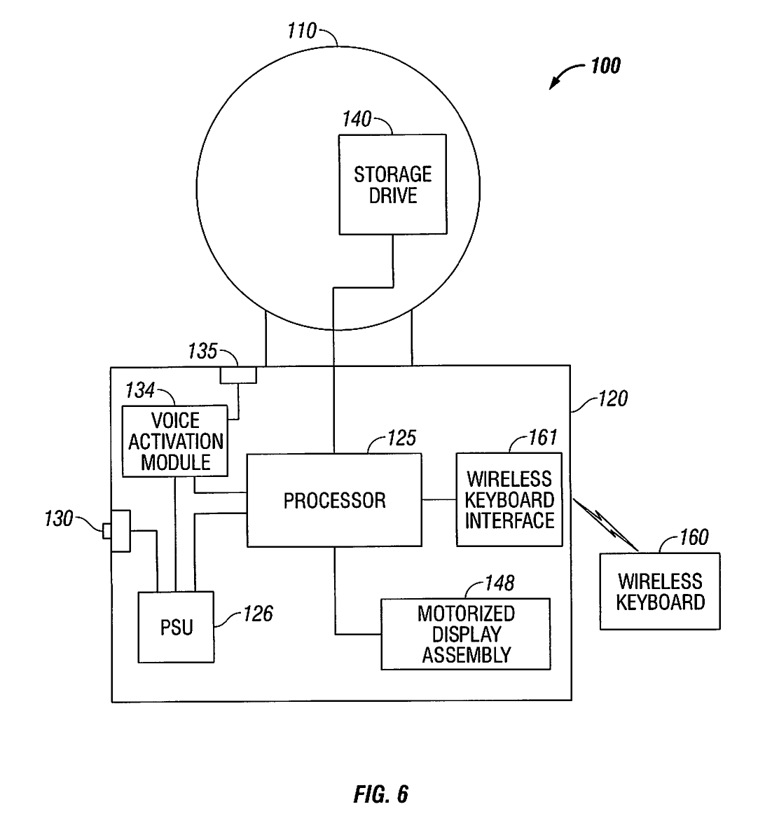

Referring to FIGS. 1 and 6, there is shown a sports ball computer 100 having a system enclosure 120 coupled to a storage drive enclosure 110 that is disposed substantially centrally upon the top surface 122 of system enclosure 120. Storage drive enclosure 110 is coupled to system enclosure 120 by pedestal 115 having an annular shape which includes a center opening, a bottom surface (not shown) that is substantially flat for mating with top surface 122, and a concave top surface (not shown) corresponding to the contour of the bottom surface of storage drive enclosure 110. Storage drive enclosure 110, system enclosure 120 and pedestal 115 can be joined by any suitable means, such as threaded fasteners or adhesive. Pedestal 115 can be integrally formed with at least one of system enclosure and/or spherical storage enclosure 110. Storage drive enclosure 110 further includes an opening disposed upon the bottom surface thereof (not shown) which corresponds to an opening disposed upon the top surface of system enclosure 120. The openings describing a passage through which power and data cables between system enclosure 120 and spherical storage drive enclosure 110 are routed.

In accordance with the present disclosure, storage drive enclosure 110 preferably has an appearance which faithfully replicates the appearance of a sports ball. Depending upon the type of ball, storage drive enclosure 110 can have a substantially spherical shape of a ball such as a basketball, soccer ball, and the like, or, storage drive enclosure 110 can have another shape, such as the substantially pointed prolate spheroid shape, or the substantially rotated vesica piscis shape, of an American football. Preferably, the outer covering of storage drive enclosure 110 is constructed of a material which resembles the texture, color and appearance of a genuine sports ball of the same type. Alternatively, the outer covering of storage drive enclosure 110 can be constructed from genuine sports ball material, such as leather, pigskin, and the like.

Preferably, the exterior surface of system enclosure 120 has an attractive appearance. System enclosure 120 may be constructed of any suitable materials such as sheet metal, aluminum, wood, or plastic, or a combination thereof. In an embodiment, system enclosure is constructed of formed sheet metal having a wooden veneer finish.

System enclosure 120 includes components of a personal computer which will be familiar to one skilled in the art, including without limitation motherboard having at least one processor 125; a power supply unit 126; at least one storage device such as a hard drive; a display interface. System enclosure 120 includes a wireless keyboard interface (not shown) for communicating with a wireless keyboard 160 using, for example, radiofrequency (RF) signals or infrared (IR) optical signals complying with the Bluetooth or IrDA standards, respectively, or using any other suitable encoding method. Wireless keyboard 160 includes an integrated pointing device 162 such as a touchpad, trackball, pointing stick, or other suitable pointing device.

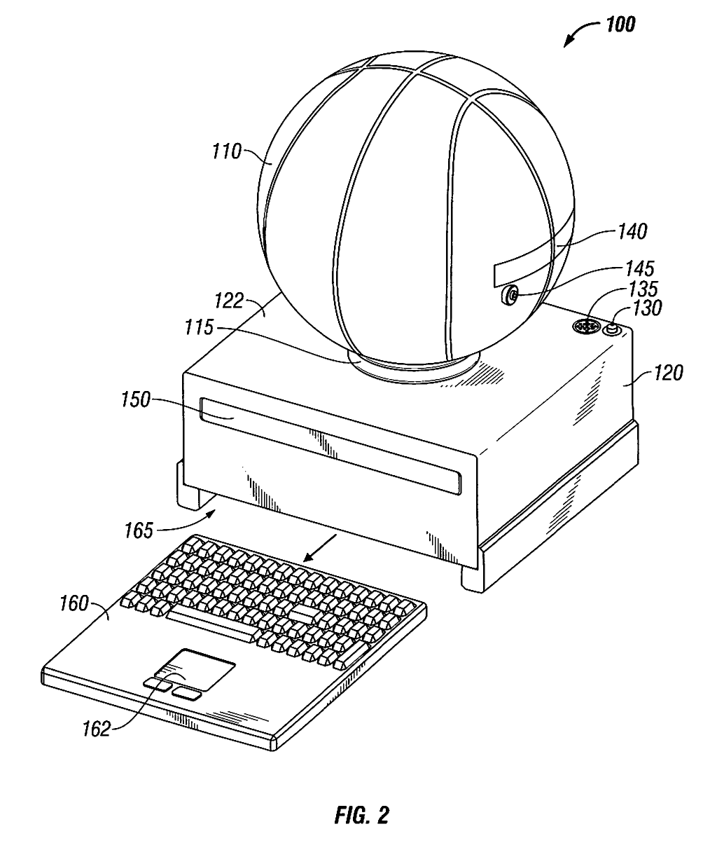

As can be seen with reference to FIG. 2, system enclosure 120 includes a storage recess 165 dimensioned to accept wireless keyboard 160 when not in use. As can be appreciated, keyboard 160 can be moved into, and out of, storage recess 165 by manually sliding it along the desktop. In an embodiment, recess 165 includes a push-to-lock/push-to-release “touch latch” for retaining keyboard 160 within recess 165 while stored, and for ejecting keyboard 160 from recess 165 upon release from storage, and for generally imparting a satisfying tactile feel to the act of keyboard stowage and deployment.

System enclosure 120 further includes a voice activation module 134 having a microphone 135 for receiving spoken commands from the user for activating, and optionally or additionally, operating the computer. The voice activation module 134 is configured to respond to spoken commands regardless of whether the computer is powered on or powered off. The voice activation module 134 can optionally include, or interoperate with, a software program configured to execute on the at least one processor for accepting user inputs related to the operation of the voice module, including, as example only, voice recognition training, association of voice commands to the desired operation to be performed by the computer in response thereto, and activation and deactivation of the voice recognition module. In an embodiment, voice activation module 134 is configured to activate power supply unit 126. System enclosure 120 additionally includes power switch 130, which can operate in a push-on/push-off fashion, for powering the computer on and off manually, i.e., activating the power supply unit without using spoken commands.

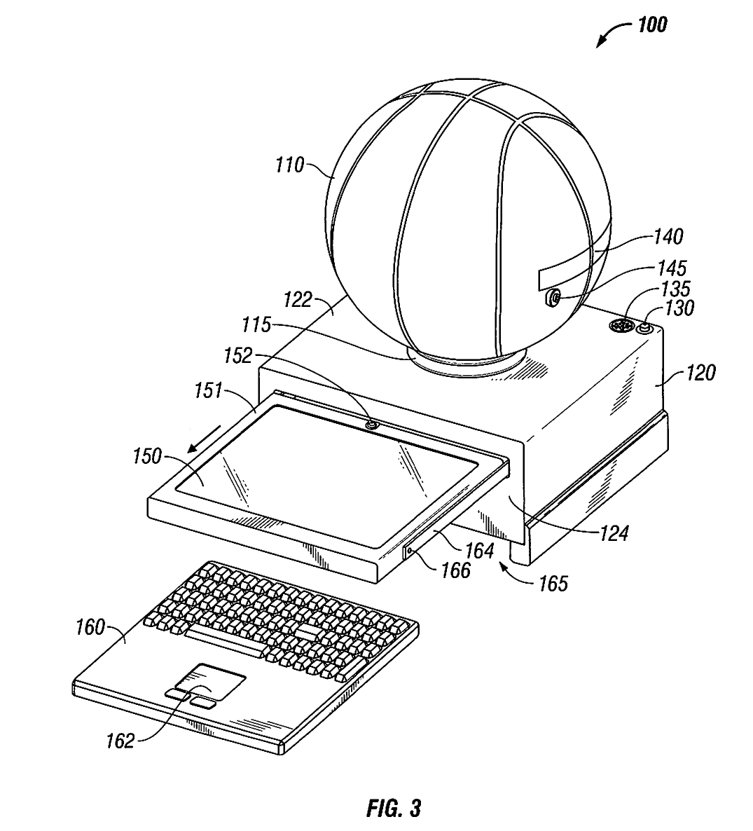

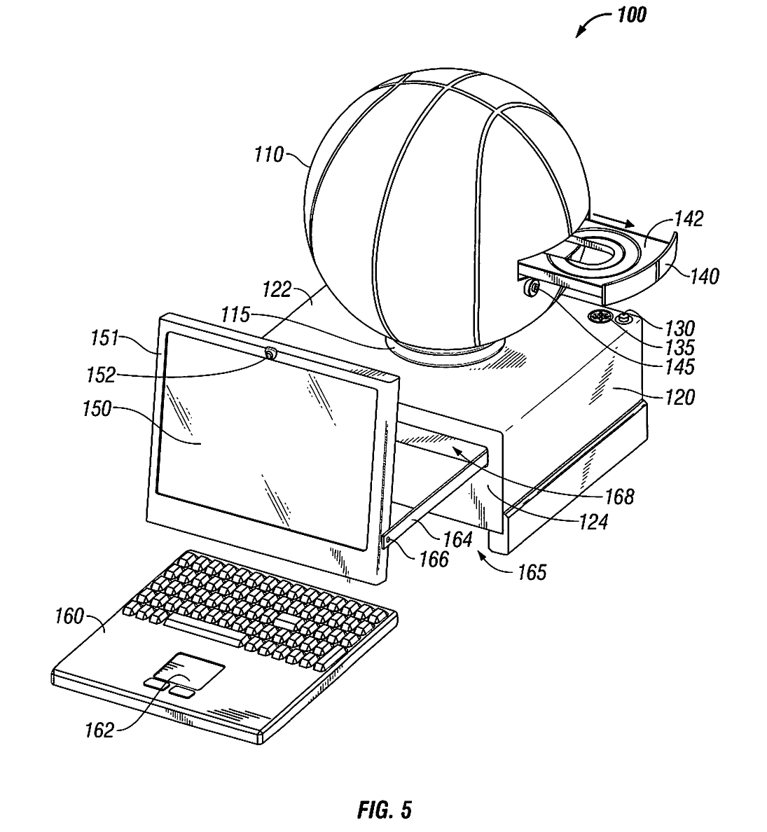

With reference now to FIGS. 3, 4, and 5, sports ball computer 100 further includes a display assembly 148 that includes a screen 150 having a stored position and a viewing position. Screen 150 is pivotably mounted to at least one motorized sliding member 164 by at least one motorized pivot 166. When the computer is deactivated, i.e., powered off, screen 150 is stored within display storage slot 168. In this configuration, i.e., in the stored position, screen 150 has been rotated into substantial alignment with the at least one motorized sliding member 164, and the at least one motorized sliding member 164 has moved into a retracted posture within the system enclosure 120, thereby drawing screen 150 into the system enclosure 120 as will be readily appreciated. Screen 150 further includes camera 152 for capturing still photographs and/or video. In an embodiment, camera 152 is configured for videoconferencing.

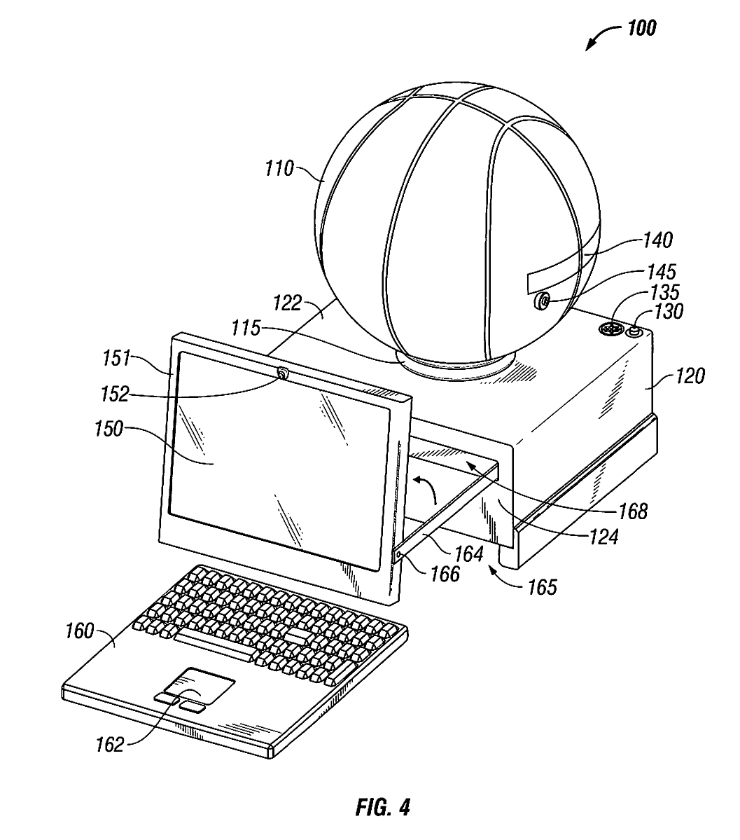

Upon activation of the computer 100, which can be by voice command or by manual actuation of power switch 130, the at least one motorized sliding member 164 moves outward from the system enclosure 120 thereby drawing screen 150 outward from display storage slot 168, as best illustrated in FIG. 3. Display 150 continues to move outward on the at least one motorized sliding member 164 until the top edge 151 of display 150 has cleared front surface 124 of system enclosure 120. At this point, further outward motion of the at least one motorized sliding member 164 ceases and the at least one motorized pivot 166 is activated in a forward mode, thereby causing screen 150 to be rotated forward until coming to rest upon reaching the viewing position as best shown in FIG. 4. In an embodiment, the angle of the screen 150 at viewing position is user adjustable, by, for example, mechanical adjustment (not shown) of the at least one motorized pivot 166, or by a software program configured to execute on the at least one processor for accepting user inputs related to the viewing angle of screen 150.

Substantially concurrently with the aforesaid display activation, computer 100 performs a bootup, wake-from-standby, wake-from-hibernate, or similar activation operation whereby the computer 100 initializes, and/or otherwise becomes ready for use as will be familiar to the skilled artisan. Preferably, computer 100 will be ready for use no later than the time at which screen 150 reaches the viewing position.

Storage drive enclosure 110 includes at least one storage drive 140 for reading and, optionally, writing, media compliant with the various CD and DVD formats which will be familiar to the skilled practitioner. Storage drive 140 includes a tray 142 and a tray pushbutton 145, and is operably coupled to the at least one processor as is well-known. Preferably, the outer face of tray 142 includes a covering having a texture, color and appearance that resembles the sports ball appearance of storage drive enclosure 110 such that, when retracted, the face plate of tray 142 is flush with, and visually blends with, the outer surface of storage drive enclosure 110.

Once activated, the sports computer 100 is available for use in the customary manner. The user can move the wireless keyboard 160 into any desired position within its wireless range, which, for example, can be approximately 30 feet when using RF communications in accordance with the Bluetooth protocol.

After concluding a period of use, the user may decide to deactivate the computer 100, which can be accomplished by, for example, actuating power button 130, by selecting a suitable “shutdown” command provided by the operating system, or by voice command. Upon deactivation, screen 150 moves from viewing position to stored position in a fashion substantially the reverse of activation. The at least one motorized pivot 166 is activated in a downward mode, causing screen 150 to rotate downward until reaching a substantially horizontal posture wherein screen 150 is aligned for insertion into display storage slot 168. Thereafter, the at least one motorized sliding member 164 moves inward into the system enclosure 120 thereby retracting screen 150 into display storage slot 168, i.e., into stored position. Substantially concurrently with the aforesaid display deactivation, computer 100 performs a shutdown, or enters a standby or hibernation state, in accordance with the deactivation command issued by the user. If desired, the wireless keyboard 160 can be returned to storage recess 165.

In an embodiment, the computer 100 is configured as a video DVD player having the capability to read a video DVD disc that has been loaded into the at least one storage drive 140, and display the contents thereof on display 150. In yet another embodiment, the computer 100 is configured as a television wherein system enclosure 120 includes a television tuner that is operatively coupled to the at least one processor for receiving television signals, such as NTSC, PAL, SECAM, ATSC, QAM or other broadcast television standard known now or in the future. Optionally or alternatively, computer 100 is further configured as a digital video recorder (DVR) for recording television broadcasts for later viewing on display 150.

It will be appreciated that variations of the above-disclosed and other features and functions, or alternatives thereof, may be desirably combined into many other different systems or applications. Various presently unforeseen or unanticipated alternatives, modifications, variations or improvements therein may be subsequently made by those skilled in the art which are also intended to be encompassed by the following claims. The claims can encompass embodiments in hardware, software, or a combination thereof.

What is claimed is:

1. A sports ball computer, comprising:
a system enclosure comprising a display assembly, wherein the display assembly includes a display screen having a stored position and a viewing position, the display assembly further including a motorized drive configured to move the display screen to the stored position upon deactivation of the sports ball computer, and to move the display screen to the viewing position upon activation of the sports ball computer; and
a storage drive enclosure having a generally sports ball-like shape disposed upon the upper surface of the system enclosure.

2. The sports ball computer of claim 1, wherein the display screen further comprises a camera.

3. The sports ball computer of claim 1, wherein the storage drive enclosure has a substantially spherical shape.

4. The sports ball computer of claim 1, wherein the storage drive enclosure has a substantially pointed prolate spheroid shape.

5. The sports ball computer of claim 1, the system enclosure further comprises a voice activation module configured to receive spoken commands for activating and deactivating the sports ball computer.

6. The sports ball computer of claim 1, wherein the system enclosure further comprises a keyboard interface; and
a keyboard configured to communicate with the keyboard interface by a communication medium.

7. The sports ball computer of claim 6, wherein the keyboard interface is a wireless keyboard interface; and
the communication medium is a wireless communication medium selected from the group consisting of radiofrequency signals and optical signals.

8. The sports ball computer of claim 7, wherein the radiofrequency signal is a Bluetooth signal.

9. The sports ball computer of claim 7, wherein the optical signal is an IrDA signal.

10. The sports ball computer of claim 6, wherein the keyboard comprises an integrated pointing device.

11. The sports ball computer of claim 10, wherein the integrated pointing device is selected from the group consisting of a touchpad, a trackball, a pointing stick, and a mouse.

12. The sports ball computer of claim 6, wherein the system enclosure further comprises a cavity disposed thereupon for storing the keyboard.

13. A computer enclosure, comprising:
a system enclosure further comprising:
a display assembly including a display screen having a stored position and a viewing position, the display assembly further including a motorized drive configured to move the display screen to the stored position, and to move the display screen to the viewing position; and
a power supply unit; and
a storage drive enclosure configured to house at least one storage drive.

14. The computer enclosure of claim 13, wherein the system enclosure further comprises a voice activation module operatively coupled to the power supply unit for activating and deactivating the power supply unit.

15. The computer enclosure of claim 13, wherein the system enclosure further comprises a voice activation module operatively coupled to the display assembly unit for activating and deactivating the display assembly unit.

16. The computer enclosure of claim 13, wherein the storage drive enclosure has a substantially spherical shape.

17. The sports ball computer of claim 13, wherein the storage drive enclosure has a substantially pointed prolate spheroid shape.

18. A method of operating a personal computer, comprising:
providing a motorized display assembly having a display screen configured to move between a stored position and a viewing position;
upon activation of the personal computer, causing the display screen to move from the stored position to the viewing position; and
upon deactivation of the personal computer, causing the display screen to move from the viewing position to the stored position.

19. The method of claim 18, wherein the display screen is substantially hidden from view while in the stored position.

20. The method of claim 18, wherein activation of the personal computer is by voice activation.

21. The method of claim 18, further comprising:
providing a wireless keyboard for use with the personal computer;
providing a storage cavity within the personal computer for storing the wireless keyboard;
removing the wireless keyboard from the storage cavity for use; and
returning the wireless keyboard to the storage cavity for storage.
